(19) United States
(12) Patent Application Publication
(10) Pub. No.: US 2016/0099399 A1
(43) Pub. Date: Apr. 7, 2016

(54) METHOD FOR MANUFACTURING A THERMOELECTRIC MODULE BASED ON A POLYMER FILM

(71) Applicant: Commissariat A L'Energie Atomique Et Aux Energies Alternatives, Paris (FR)

(72) Inventors: Nicolas MASSONET, Grenoble (FR); Alexandre CARELLA, Mazeres Lezons (FR); Jean-Pierre SIMONATO, Sassenage (FR)

(21) Appl. No.: 14/969,518

(22) Filed: Dec. 15, 2015

Related U.S. Application Data
(63) Continuation of application No. PCT/FR2014/051806, filed on Jul. 15, 2014.

(30) Foreign Application Priority Data
Jul. 24, 2013 (FR) 13.57310

(51) Int. Cl. H01L 35/34; H01L 35/24

(52) U.S. Cl. CPC H01L 35/34; H01L 35/24

(57) ABSTRACT

A method of manufacturing a thermoelectric module including a substrate and at least one conductive or semiconductor polymer film deposited on a surface of the substrate, the method including a step of manufacturing the conductive polymer film independently from the surface of the substrate and transferring the conductive polymer film onto the surface of the substrate. The transfer comprises: immersing the conductive polymer film in a transfer bath to obtain a conductive polymer film which is solvated, self-supporting, and capable of matching the shape of the substrate surface; applying the conductive polymer film in its solvated state on the substrate to match the shape of the surface thereof; and drying the solvated conductive polymer film.

### FIELD OF THE INVENTION

The invention relates to the manufacturing of thermoelectric modules, for example, flow sensors or electric power generation modules, based on polymer materials.

### BACKGROUND

Thermoelectric modules usually comprise one or a plurality of thermoelectric junctions between two materials, generally taking the shape of bands, or “tabs” arranged at the surface of an electrically-insulating substrate and having different Seebeck coefficients. Such junctions particularly enable to generate electric power when they are submitted to a temperature gradient, or to generate heat when they are crossed by an electric current. For example, a thermoelectric flow sensor enables to measure a unidirectional heat flow crossing a thermoelectric junction by generating a potential difference having its value depending on the intensity of the heat flow.

As know, for example, from document “Matériaux à effets thermoélectriques” of C. Godart, Techniques de l′Ingénieur, N1500, 1-16, 2009, the materials best suited to form thermoelectric modules have both good thermoelectric properties, particularly a high Seebeck coefficient and a high thermoelectric power coefficient, a good electric conductivity, and a low heat conductivity. Conductive or semiconductor polymers, which have such properties, have thus been used to form thermoelectric modules, particularly PEDOT:PSS (poly(3,4 ethylene-dioxythiophene), currently called “PEDOT”, combined with poly(styrene sulfonate), currently called “PSS”. Particularly, a polymer film constitutive of a thermoelectric junction is directly deposited on the substrate of the thermoelectric module by means of a spray, spin coating, or drop casting technique.

Such a manufacturing however has a number of disadvantages. First, such deposition techniques do not enable to reliably deposit a material from the moment that the deposition surface is not planar, which thus limits the geometry that thermoelectric modules may take. Further, the forming of a film having exactly the desired geometry directly during the deposition requires using masks, which proves to be expensive. Further, a thermoelectric module substrate is not necessarily suited to the deposition of a polymer film. In particular, if the deposited polymer solution and the substrate have very different surface energies, the deposit turns out being of poor quality, the thermoelectric module thus being fragile. Finally, physico-chemical treatments of the polymer film are sometimes necessary to optimize the properties thereof Now, such treatments require, in particular, an immersion of the film into one or a plurality of baths and drying steps, which may decrease the bonding of the film to the substrate, or even separate the film from the substrate.

### SUMMARY OF THE INVENTION

The present invention aims at providing a method of manufacturing a thermoelectric module which enables to optimize the properties of the polymer film and which enables to form complex geometries for the thermoelectric module substrate and/or for the film.

To achieve this, the invention aims at a method of manufacturing a thermoelectric module comprising a substrate and at least one conductive or semiconductor polymer film deposited on a surface of the substrate.

According to the invention, the conductive polymer film is manufactured independently from the surface of the substrate and the conductive polymer film is then transferred onto the surface of the substrate. The manufacturing of the conductive polymer film comprises:
depositing the conductive polymer film on a deposition substrate; and
immersing the conductive polymer film and the deposition substrate in a bath to release the conductive polymer film.

Further, the transfer comprises:
immersing the conductive polymer film in a transfer bath to obtain a conductive polymer film which is solvated, self-supporting, and capable of matching the shape of the substrate surface;
applying the conductive polymer film in its solvated state on the substrate to match the shape of the surface thereof; an
drying the solvated conductive polymer film.

Particularly, the polymer film is directly deposited on the deposition substrate and no additional layer is provided to improve the mechanical behavior of the polymer film. In particular, the stack only formed of the polymer film and of the substrate is immersed in the bath for releasing the polymer film.

“Polymer film” here means a fully polymeric material or a hybrid material comprising a polymer matrix having an organic or inorganic material added thereto, particularly to improve the electric, chemical, mechanical, thermoelectric, and/or heat transfer properties. For example, metal or semiconductor elements may be added. In the following, expression “polymer” when designating a material refers to the polymer as such, with no additive material.

“Independently formed” here means that the polymer film is formed on a substrate different from the substrate of the thermodynamic module onto which it is intended to be transferred. Of course, it should be understood that the geometry of the polymer film may depend on the shape of the substrate.

“Transfer bath” here means a liquid which has the property of the modifying the solvation state of the polymer by making it self-supporting.

In other words, forming the polymer film independently from the substrate of the thermoelectric module enables to optimize its properties according to the targeted application. Further, it is also possible to more simply and/or more accurately define the final geometry that the latter should take.

It can however be observed that polymer films are generally rigid and brittle once dried. Their manipulation is thus difficult and placing a polymer in its dry final state over a substrate comprises a risk of breaking the film, this risk being all the greater as the substrate surface is not planar.

However, when the polymer film is immersed in a so-called “transfer” bath, it first exhibits a modification of its rigidity due to a so-called “solvation” phenomenon. By removing the film from the bath after an adequate immersion time period, a solvated film which is flexible and self-supporting is then obtained. According to the invention, once the polymer film has been manufactured, it is thus solvated to have a suitable flexibility to be able to match the shape of the surface of the thermoelectric module substrate, and transferred in its solvated state onto said substrate. It may thus be transferred on a substrate of complex geometry, for example, a cylindrical substrate or a substrate with acute angles.

According to an embodiment of the invention, the manufacturing of the conductive polymer film comprises depositing in a single operation a layer having a thickness greater than 1 micrometer directly on the deposition substrate, particularly a thickness in the range from 1 micrometer to 100 micrometers. Such thicknesses particularly enable to form high-power thermoelectric modules.

More particularly, the manufacturing of the conductive polymer film comprises depositing on the deposition substrate a conductive polymer film having an area greater than that of the conductive polymer film to be transferred on the substrate of the thermoelectric module and, consecutively to the immersion in the bath, to release the conductive polymer film from the deposition substrate, the method comprises:
transferring the released conductive polymer film onto a cutting substrate;
drying the conductive polymer film;
cutting the polymer film to the dimensions desired for it; and
immersing the cut conductive polymer film and the cutting substrate in a bath to release the cut conductive polymer film.

As a variation, the manufacturing of the conductive polymer film comprises depositing on the deposition substrate a conductive polymer film having an area greater than that of the conductive polymer film to be transferred on the substrate of the thermoelectric module and, prior to the immersion in the bath to release the conductive polymer film from the deposition substrate, the method comprises:
drying the conductive polymer film; and
cutting the polymer film to the dimensions desired for it.

Advantageously, the transfer bath used for the transfer is different from the conductive polymer film manufacturing bath.

According to an embodiment, the transfer of the polymer film onto the surface of the thermoelectric module substrate comprises positioning the conductive polymer film by sliding on the substrate surface.

According to an embodiment, the drying of the conductive polymer film comprises the rinsing thereof with a rinsing fluid to decrease or eliminate the solvated state of the polymer film.

According to an embodiment, the conductive polymer film comprises a heterocyclic aromatic compound, particularly a thiophene. More particularly, the conductive polymer film comprises poly-3-hexylthiophene or poly(3,4 ethylene dioxythiophene), advantageously combined with polystyrene sodium sulfonate) or toluene sulfonate.

Particularly, the transfer bath used for the transfer of the conductive polymer film comprises dimethylsulfoxide or n-methylpyrrolidone or ethylene glycol, or an alcohol, or water, or a carbonyl compound or an organochlorine compound or a mixture of at least two of these.

### BRIEF DESCRIPTION OF THE DRAWINGS

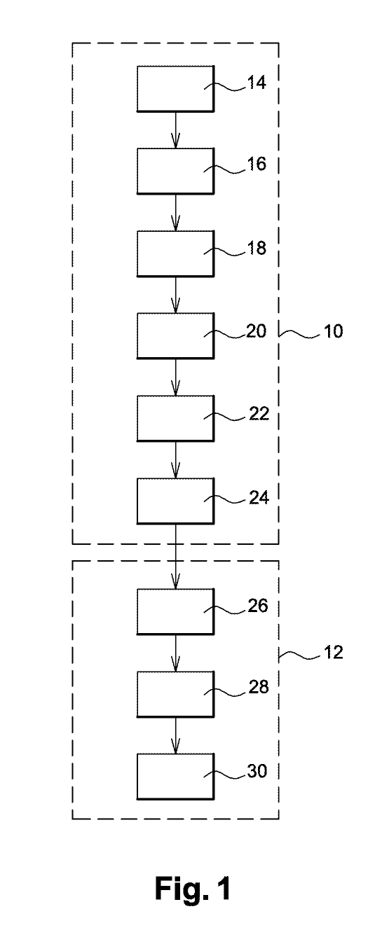

The invention will be better understood on reading of the following description provided as an example only in relation with the flowchart of FIG. 1 illustrating a method of manufacturing a thermoelectric module according to the invention.

### DETAILED DESCRIPTION OF THE INVENTION

Referring to FIG. 1, a method of manufacturing a thermoelectric module according to the invention comprises a step 10 of manufacturing a conductive polymer film and a step 12 of transferring the film onto a substrate of the thermoelectric module.

Particularly, manufacturing step 10 comprises a step 16 of synthesis of a precursor of the organic or hybrid material constitutive of the film to prepare the deposition of the film on an appropriate deposition substrate.

The preparation of a precursor of a polymer or hybrid material is known per se, and the precursor may be a solution, for example commercial, comprising polymer, or a monomer thereof, dissolved in a solvent. An organic or inorganic material in powder form may be added to or is already present in the precursor solution, or the additive material is dispersed in a solvent compatible with the precursor solution, after which the two solutions are then mixed.

Step 10 of manufacturing the polymer film further comprises a step 14 of depositing the precursor solution directly on a deposition substrate, the latter being advantageously selected to favor a quality deposition of the solution. In the case where the precursor solution comprises monomers, the polymerization is advantageously performed on the substrate.

For example, the solution is directly deposited on the substrate by means of a drop casting, a spin coating, a doctor blade deposition, or an inkjet-type deposition, by depositing a controlled quantity of solution of the substrate surface.

When the precursor solution is a solution based on monomers, the method carries on with the application at 16 of conditions controlled in terms of temperature, pressure, and chemical composition of the atmosphere to obtain the polymerization of the monomers or, in the case of a radiation-crosslinkable polymer, an appropriate radiation is applied to the deposited solution. Particularly, the polymerization of EDOT (3,4 ethylene dioxythiophene) monomers to obtain PEDOT is performed by electrochemistry or by means of an oxidizing species, for example, an iron (III) complex coordinated with paratoluene sulfonate ions.

As a variation, the polymerization is performed before the deposition of the solution on the deposition substrate or the solution is already polymerized, as is for example the case for certain commercial solutions.

The deposited solution is then heated at 18. Particularly, the solvent contained in the deposited solution is evaporated and a step of annealing from 20 to 200° C., preferably from 20 to 100° C., is optionally implemented. The annealing especially allows a structural rearrangement of the polymer domains, a deployment of the molecular chains, and an improvement of the electric conductivity of the deposited polymer film. In the case of a hybrid film, the annealing also enables to improve the cohesion between the additive material and the polymer matrix. The annealing is further advantageously implemented under a controlled atmosphere to dehydrate the polymer, which provides a dry deposit, and/or enables to avoid any unwanted oxidation. The anneal is for example implemented in a drying chamber in vacuum conditions at temperatures in the range from 50 to 150° C. to dry the deposit as much as possible.

It is thus possible to manufacture, particularly in a single deposition step, conductive polymer films having a thickness in the range from 100 nanometers to 1 centimeter, and preferably from 200 nanometers to 1 millimeter. Particularly, a thickness greater than 1 micrometer is advantageous for high power applications of the thermoelectric module.

More particularly, the manufacturing of the polymer film contains no additional layer deposition aiming at improving the mechanical behavior of the film.

The polymer film manufacturing optionally caries on with a treatment step 20 aiming at improving the electric conductivity of the polymer film, particularly by a factor 100, and at improving the chemical stability.

More particularly, the deposition substrate and the polymer film are immersed in a bath to improve the physico-chemical properties of the deposit, as for example described in document Kim, Y. H.; Sachse, C.; Machala, M. L.; May, C.; Müller-Meskamp, L.; Leo, K. Advanced Functional Materials 2011, 21, 1076-1081. This bath especially allows a reorganization of the polymer chains, accompanied by the departure of certain chemical species which were necessary to the deposition of the precursor solution or to the polymerization of the material, but which are prejudicial because of their electric or thermoelectric properties. This type of structural doping, also called “secondary doping” for a polymer, uses a dopant species which irreversibly modifies the configuration of the polymer chains, thus easing the generation and the displacement of electric charges along the macromolecules. This doping is for example described for polyaniline in Alan

McDiarmid et al.'s document [MacDiarmid, A. G.; Epstein, A. J. Synthetic Metals 1995, 69, 85-92.], and for PEDOT:PSS in Andreas Elschner et al.'s book [Elschner, A.; Kirchmeyer, S.; Lövenich, W.; Merker, U.; Reuter, K. PEDOT; CRC Press, 2010., chapter 9.3: “Secondary doping”].

The method then carries on with the releasing of the polymer film and optionally with the shaping thereof according to the targeted application.

Particularly, at a step 22, the stack only made of the polymer film and of its deposition substrate is immersed in a bath to separate the film from the substrate. The film then floats in the solvent bath and, due to its solvation, it is self-supporting, that is, it may be manipulated independently from any substrate, and may in particular be simply retrieved by means of pliers or of a similar mechanical system. When the film has a low mechanical resistance and there is a risk of tearing by pinching, the film may also for example be retrieved on a new substrate or by filtering of the solvent bath. Certain baths used to obtain the structural doping of the polymer also enable to separate the film from the substrate, such as for example an ethylene glycol bath for PEDOT:PSS. In such a case, steps 20 and 22 are confounded.

Optionally, at a next step 24, the polymer film is shaped for its subsequent transfer onto the thermoelectric module substrate. For example, the polymer film is deposited on a large surface area to collectively manufacture a plurality of polymer bands or “tabs”, constitutive of the thermoelectric module, and each band is individualized by cutting.

Particularly, the film is retrieved or transferred on a cutting substrate, and is then dried to have a sufficient rigidity for its cutting. Once the film has dried, it is then cut to the final dimensions desired for the tabs. The cut film and the cutting substrate are then immersed in a bath to release the tabs which then freely float in the solvent bath. The release is for example obtained by slightly stirring the substrate in the bath or by mechanically detaching the tabs from their substrate by pulling them to peel the substrate. As a variation, the film is directly cut on the deposition substrate, after which the cut elements are released by immersion in a solvent bath. The first variation has the advantage of not damaging the deposition substrate, which may be used again and of having a smaller number of steps. The second variation enables to be free as to the selection of the cutting support, and thus also of the cutting techniques. Particularly, a cutting with scissors, which is simple and accurate, may be used.

Step 14 of transferring the polymer film optionally starts, at 26, by retrieving the polymer film and immersing it in a new bath, called “transfer” bath, to give it the appropriate solvation for its transfer onto the thermoelectric module substrate. The immersion in the bath used to separate the film from the deposition substrate, or possibly from the cutting support, may indeed appear to be insufficient to obtain the desired flexibility for the transfer of the polymer film onto the thermoelectric module substrate. Further, the liquids used for the baths may implement different physico-chemical mechanisms acting on the film flexibility, but also on the bonding thereof to the thermoelectric module substrate.

By choosing two different baths, it is thus possible to select a bath optimized for the release of the film and a bath optimized for the transfer of the film onto the final substrate.

Advantageously, a rinsing and/or drying are implemented after the immersion in the bath used to release the polymer film to make the most of the properties of the second bath for the film transfer. A single bath is however also possible, the obtained solvation being likely to be satisfactory for the final transfer onto the thermoelectric module substrate. A second bath may also be used to rinse the liquid of the first bath.

The polymer film is then transferred, at 28, in its solvated state onto the substrate of the thermoelectric module, directly at the location desired for it, or slid on the substrate to be positioned at said location. The solvated state of the polymer film enables not only to adapt the film to the substrate surface, including when the latter is non planar, but also provides an increased bonding to the substrate while enabling to slide the film on the substrate, which eases the positioning thereof. When a plurality of tabs, for example resulting from the cutting of the initial polymer film, is provided for the thermoelectric module, said tabs are placed at their respective locations.

The method carries on with a step 30 of drying and completing the thermoelectric module, implemented when the polymer film or the tabs are in place on the thermoelectric module substrate. The implementing of the drying and of the completion, as well as their sequence, may be a function of the nature of the polymer film, of the geometry of the module, and of the bath used to set the solvation state of the polymer film. For example, a step of drying the transferred polymer film is implemented in given temperature and pressure conditions, particularly by means of an anneal. For example, for a PEDOT:PSS solvated by immersion in an ethylene glycol bath, an annealing temperature in the range from 50° C. to 200° C., for example, 160° C., at ambient pressure and under an ambient atmosphere is implemented for 1 hour. Such conditions enable to obtain electric conductivities in the range from 1,000 to 1,600 S/m. A simple step of drying by evaporation, and accordingly with no anneal, is also possible, for example, when the second bath is an ethanol bath.

Preferably, a rinsing with a solvent different from that used for the solvation intended for the transfer is implemented prior to the drying to eliminate traces of the transfer solvent, which also enables to set the position of the polymer film.

Once dried, and possibly rinsed, the polymer film remains laid against the substrate and is no longer self-supporting. A compression phase may also be implemented before or after the drying to maximize the flat laying of the film.

Finally, a step of encapsulating the polymer film and the substrate may also be implemented to definitively secure the films and protect them against mechanical or physico-chemical degradations such as oxidation, for example, and to improve the mechanical behavior.

Polymer films capable of being shaped and transferred by the method according to the invention are all polymer or hybrid materials. For example, the organic portion of the material may be formed of heterocyclic aromatic compounds such as thiophenes and their derivatives, preferably P3HT (poly-3-hexylthiophene) and preferably PEDOT, or polypyrroles and their derivatives, arylamines and their derivatives, preferably PTA (polytriarylamine), polyacetylene and its derivatives, isochromenones and their derivatives, polyanilines and their derivatives, polyarylene ethynylenes and their derivatives, polyarylene vinylenes and their derivatives, polycarbazoles, poly(2,7-carbazolylene vinylene), heterocyclic macrocycles such as porphyrins, phtalocyanines and their derivatives.

This organic portion may also be an insulating polymer, such as polyvinyl acetate, polystyrene, polyethylene.

The additive material, when present, may be of any type, particularly a metallic inorganic material, for example, metal nanoparticles, such as gold nanoparticles, metal nanowires, such as silver nanowires, metal powders, such as indium, selenium, or lead powders, or an inorganic semiconductor material, particularly nanoparticles or silicon, germanium, zinc oxide, tellurium, bismuth, antimony nanowires, or an alloy of semiconductors, such as for example, bismuth telluride.

The additive material may also take the form of carbon nanotubes of metallic or semi-conductor type, of graphene, or of fullerene.

Different solvents may be envisaged, according to the considered polymer, but also to the physico-chemical properties desired for the polymer.

For thiophene derivatives, such as P3HT or PEDOT, the solvents preferred for the transfer of the films are those performing a secondary doping on the polymer, particularly polyols (for example, glycerol, ethylene glycol, sorbitol, and meso-erythritol), alcohols having a secondary polar group (for example, 2-nitroethanol and methoxyphenol), ether-oxides and thioethers (for example, diethylene glycol, thiodiethanol, and tetrahydrofuran), amides and imides (for example, N,N-dimethylformamide, N,N-dimethyl acetamide, N-methylpyrrolidone, and succinimide), sulfoxides (for example, dimethyl sulfoxide), or ionic liquids (for example, 1-butyl-3-methylimidazolium tetrafluoroborate and 1-ethyl-3 -methylimidazolium tetracyanoborate).

The bath used for the transfer may also be a conventional bath such as an alcohol (for example, ethanol, butanol, isopropanol), water, a carbonyl compound (for example, acetone or butan-2-one), an organochlorine compound (for example, tricholoromethane or dichloromethane), or a mixture of these compounds.

The immersion in a bath to solvate and/or release the polymer film is preferably carried out at cold temperature. The duration of the immersion depends on the nature of the polymer film, of the substrate, and of the bath, and may vary from a few tens of seconds to 1 hour, the minimum duration corresponding to the time when the film mechanically separates from its substrate.

Particularly, when the polymer film is a PEDOT:PSS film deposited on a glass, plastic, or aluminum substrate, an immersion of the film and of the substrate in a dimethylsulfoxide, n-methylpyrrolidone, or ethylene glycol bath for a time period in the range from 10 minutes to one week enables to separate the film from the substrate. It can be observed that PEDOT:PSS generally separates in 20 minutes. For a longer immersion duration, it can be observed that the mechanical and chemical properties of the film remain stable, including when the film is immersed in the bath for a plurality of weeks.

It should further be noted that the bath used to separate the film from the deposition substrate may also be suitable to obtain the desired solvated state for the transfer onto the final substrate, such as for example an ethylene glycol bath.

Further, an immersion of the PEDOT:PSS film in an ethanol bath for a duration in the range from 1 second to 1 hour enables to adjust the solvation of the film to ease its transfer onto a substrate, including onto a substrate comprising protrusions and 90° angles. Particularly, the immersion in the ethanol bath makes the film more rigid, and thus easier to manipulate, and also rinses away the ethylene glycol. The modification of the rigidity of the PEDOT:PPS is almost immediate. The total rinsing of the ethylene glycol however requires several minutes of immersion, generally 10 minutes.

The substrate of the thermoelectric module having the polymer film transferred onto it and the intermediate substrate used to shape the film are for example made of glass, of polymers, possibly flexible and/or transparent, such as PEN (polyethylene naphthalate), PET (polyethylene terephthalate), of woven or nonwoven textile, of ceramic or of paper. The intermediate substrates may also be metallic, for example steel plates or aluminum foils, to ease the operations of compression, cutting, or shaping the tabs of the thermo-electric module.

### EXAMPLE 1

Thermoelectric module manufactured on a glass plate from a PEDOT:PSS solution, for example, the solution commercialized by Heraeus Precious Metals GmbH under reference “HERAEUS CLEVIOS PH 1000”.

A PEDOT:PSS film is drop cast on a glass substrate of dimension 5.0×2.5 cm². After a deposition of 0.8 ml of the HERAEUS CLEVIOS PH1000 commercial solution, the material is left for three days in the ambient pressure and temperature conditions. To complete the drying, it is then left for half a day in a drying chamber at 100° C. under vacuum. The obtained material is a film having a 10-micrometer thickness of PEDOT:PSS fastened to the glass substrate.

The thin film and its glass substrate are then placed in an ethylene glycol bath for 30 minutes. The film then separates from the glass plate and floats in the bath independently from the substrate. The film is retrieved by means of flat pliers, and then dipped for one minute in an ethanol bath to dilute the remanent ethylene glycol, and then deposited on an aluminum foil. The film transferred onto the aluminum is then passed in the drying chamber for 30 minutes at 100° C. under vacuum.

The aluminum foil and the PEDOT:PSS film at its surface are then cut with a box cutter in the form of bands of approximately 0.25×2.5 cm². The bands are then dipped again into an ethylene glycol bath, which results in separating the PEDOT:PSS from the aluminum. PEDOT:PSS bands of approximately 0.25×2.5 cm² having a 10-micrometer thickness are thus retrieved.

The bands are dipped for one minute in an ethanol bath, and then deposited parallel to one another on a glass support of 5×5 cm² forming the substrate of the thermoelectric module. The substrate is placed in the drying chamber at 100° C. under vacuum for 30 minutes.

The geometry selected for this module is adequate for a heat source centered on the glass plate. Silver lacquer is used to connect the bands, or “tabs” of the module to one another, thereby creating electric junctions between the PEDOT:PSS, which is a p-type semi-conductor polymer, and the silver lacquer. The silver lacquer is then heated on a heating plate at 80° C. for one hour. To complete the module, the latter is encapsulated, for example, by means of adhesive Kapton 8 bands to protect the tabs of the module. The module is then connected to a multimeter and tested by using the finger as a heat source. The measured Seebeck coefficient of the module thus manufactured is 120 μV/K.

### EXAMPLE 2

Thermoelectric module manufactured on a cylindrical glass vial from a PEDOT:PSS solution, for example, the Heraeus Clevios PH1000 solution.

A PEDOT:PSS film is drop cast on a glass substrate of dimension 5×5 cm². After a deposition of 2 ml of the HERAEUS CLEVIOS PH1000 commercial solution, the film and its substrate are left for five days in the ambient pressure and temperature conditions. To complete the drying, the film and the substrate are then left for three days in a drying chamber at 80° C. under vacuum. A film having a 10-micrometer thickness of PEDOT:PSS fastened to the glass substrate is thus obtained.

The dry film is cut into eight strips with a box cutter, directly on the glass plate. The cutting is easy since the film is well fastened to the surface. The eight polymer strips remain bonded to the surface. The polymer thus cut and its substrate are placed in an ethylene glycol bath for 30 minutes. The strips separate from one another and freely float in the bath. The strips are then retrieved one by one by means of flat pliers and positioned on the lateral surface of a cylindrical glass vial. The vial with the deposited strips is placed in the drying chamber at 120° C. under vacuum for 12 hours.

The polymer strips or “tabs” are then fastened in the selected geometry, that is, parallel along the pillbox length. A deposition of commercial silver lacquer enables to create the junction between the tabs according to a thermoelectric pattern known per se. The ends of the thermoelectric module are then connected to a multimeter.

When a liquid (here, water) at 80° C. is deposited at the bottom of the pill box, a 5-mV response is recorded, which amounts to a Seebeck coefficient of approximately 90 μV/K for the module at a 25° C. ambient temperature.

### EXAMPLE 3

Thermoelectric module manufactured on a flexible adhesive substrate from a PEDOT:PSS solution, for example, the Heraeus Clevios PH1000 solution.

A PEDOT:PSS film is drop cast on a glass substrate of dimension 1.25×2.5 cm². After the deposition of 0.4 ml of the HERAEUS CLEVIOS PH1000 commercial solution, the film and the glass substrate are left for two days on a heating plate at 50° C. To complete the drying, the film and the substrate are then placed for 12 hours in a drying chamber at 100° C. under vacuum. A film having a 10-micrometer thickness of PEDOT:PSS fastened to the glass substrate is thus obtained.

The dry film is then cut into five bands parallel to the glass substrate width by means of a box cutter. Five strips of approximately 1.25×0.5 cm fastened to the deposition substrate are then obtained. The assembly is then placed in an ethylene glycol bath for 30 minutes. The strips separate from one another and then freely float in the bath. The strips are retrieved one by one by means of flat pliers and laid on blotting paper. This results in partly drying each strip, which however remains strongly solvated. The strips are then transferred from the blotting paper onto a Kapton® scotch tape pasted to an aluminum plate. The assembly is then rinsed with ethanol before being placed in a vacuum drying chamber at 50° C. for 3 days. It is then possible to detach the Kapton® scotch tape supporting the five polymer strips and to place it back on another substrate, such as a PEN film having a 125-μm thickness, for example, that referenced under trade name TEONEX. Silver lacquer tracks are then deposited between the PEDOT:PSS strips while respecting the connections of the tabs of the thermoelectric module.

After wiring to a multimeter, it is possible to measure the sensitivity of the heat flow sensor thus obtained by imposing a heat source on one of the sides of the Kapton® forming the substrate. A response of approximately 60 μV/K is measured.

### EXAMPLE 4

Thermoelectric module between the front and rear surfaces of a glass window shaped by transfer of PEDOT:PSS films.

A PEDOT:PSS solution doped with DMSO is prepared from 5 mL of the HERAEUS CLEVIOS SV4 commercial solution to which a volume of 0.5 mL of dimethylsulfoxide is added. After one night of magnetic stirring, 3.2 mL of the obtained solution are deposited on a glass plate of dimension 5.0×5.0 cm². After one week of drying in the ambient pressure and temperature conditions, the material is left for 2 days in a vacuum drying chamber at 80° C. The obtained material is a film of a 10 micrometer thickness of PEDOT:PSS fastened to the glass substrate.

The film is cut in the form of strips having a 5-cm length and a 0.5-cm width by means of a box cutter, directly on the deposition substrate.

The thin film and its glass substrate are then placed in an ethylene glycol bath and placed in a universal orbital shaker for 20 minutes. The polymer strips spontaneously detach from the substrate. They are left at rest in the ethylene glycol bath for 2 days.

Then, the strips which independently float in the ethylene glycol are retrieved with laboratory pliers, dipped for some ten seconds in an ethanol bath, and arranged on a glass plate of 10 cm by 10 cm so that half of each strip is located on the front side of the plate. Each strip, after having been roughly placed at the surface, is displaced by sliding with a gloved finger to adjust it to its final position. Still by means of a gloved finger, the strips are then folded on the rear surface and placed against the wafer so that each of them creates the junction between the front surface and the rear surface of the glass plate.

Silver lacquer is deposited by means of an applicator to connect the end located on the front side of each strip with the end located on the back side of the neighboring strip. The thermoelectric module thus formed delivers a potential difference proportional to the temperature difference between the front surface and the rear surface of the glass plate.

1. A method of manufacturing a thermoelectric module comprising a substrate and at least one conductive or semiconductor polymer film deposited on a surface of the substrate, the method comprising manufacturing the conductive polymer film independently from the surface of the substrate and transferring the conductive polymer film onto the surface of the substrate, wherein the manufacturing of the conductive polymer film comprises:
depositing the conductive polymer film directly on a deposition substrate to form a stack only comprising the polymer film and the deposition substrate; and
immersing the stack formed of the conductive polymer film and of the deposition substrate in a bath to release the conductive polymer film,
and wherein said transfer comprises:
immersing the conductive polymer film in a transfer bath to obtain a conductive polymer film which is solvated, self-supporting, and capable of matching the shape of the substrate surface;
applying the conductive polymer film in its solvated state on the substrate to match the shape of the surface thereof; and
drying the solvated conductive polymer film.

2. The method of manufacturing a thermoelectric module of claim 1, wherein the manufacturing of the conductive polymer film comprising depositing in a single operation a layer having a thickness greater than 1 micrometer directly on the deposition substrate.

3. The thermoelectric module manufacturing method of claim 2, wherein the manufacturing of the conductive polymer film comprises depositing on the deposition substrate a conductive polymer film having an area greater than that of the conductive polymer film to be transferred onto the substrate of the thermoelectric module and in that, consecutively to the immersion in the bath to release the conductive polymer film from the deposition substrate, the method comprising:
transferring the released conductive polymer film onto a cutting substrate;
drying the conductive polymer film;
cutting the polymer film to the dimensions desired for it; and
immersing the cut conductive polymer film and the cutting substrate in a bath to release the cut conductive polymer film.

4. The thermoelectric module manufacturing method of claim 2, wherein the manufacturing of the conductive polymer film comprises depositing on the deposition substrate a conductive polymer film having an area greater than that of the conductive polymer film to be transferred onto the substrate of the thermoelectric module and in that, prior to the immersion in the bath to release the conductive polymer film from the deposition substrate, the method comprising:
drying the conductive polymer film; and
cutting the polymer film to the dimensions desired for it.

5. The thermoelectric module manufacturing method of claim 2, wherein the transfer bath used for the transfer is different from the bath used for the manufacturing of the conductive polymer film.

6. The thermoelectric module manufacturing method of claim 1, wherein the transfer of the polymer film onto the surface of the substrate of the thermoelectric module comprises positioning the conductive polymer film by sliding on the substrate surface.

7. The thermoelectric module manufacturing method of claim 1, wherein the drying of the conductive polymer film comprises the rinsing thereof with a rinsing fluid to decrease or eliminate the solvated state of the polymer film.

8. The thermoelectric module manufacturing method of claim 1, wherein the conductive polymer film comprises a heterocyclic aromatic compound, particularly a thiophene.

9. The thermoelectric module manufacturing method of claim 8, wherein the conductive polymer film comprises poly-3-hexylthiophene or poly(3,4 ethylene dioxythiophene), advantageously combined with polystyrene sodium sulfonate) or toluene sulfonate.

10. The thermoelectric module manufacturing method of claim 8, wherein the transfer bath used to transfer the conductive polymer film comprises dimethylsulfoxide or n-methylpyrrolidone or ethylene glycol, or an alcohol or water, or a carbonyl compound or an organochlorine compound, or a mixture of at least two of these.
